(19) United States
(12) Patent Application Publication
(10) Pub. No.: US 2003/0070288 A1
(43) Pub. Date: Apr. 17, 2003

(54) Method and device for aligning an image sensor

(75) Inventor: Tim Ting, Shin Juang City (TW)

Correspondence Address: BACON & THOMAS, PLLC, 625 SLATERS LANE, FOURTH FLOOR, ALEXANDRIA, VA, 22314

(73) Assignee: NuCam Corporation, Taipei (TW)

(21) Appl. No.: 10/014,540

(22) Filed: Dec. 14, 2001

(30) Foreign Application Priority Data
Oct. 12, 2001 (CN) 01136390.8

(51) Int. Cl. H05K 3/20; H05K 3/30

(52) U.S. Cl. 29/832; 29/831

(57) ABSTRACT

This invention relates to a method for aligning an image sensor, comprising the steps of providing a circuit substrate and an image sensor, providing a device for aligning the image sensor with the circuit substrate, and assembling the circuit substrate, the image sensor and the device so as to maintain the preciseness and consistency of the assembly of the image sensor and the circuit substrate. Furthermore, a device for aligning an image sensor comprises a frame having a receptacle and an opening at the center thereof. The image sensor is received within the receptacle. The peripheral dimension of the image sensor is smaller than that of the opening so that the image sensor is confined in the opening. The alignment device insures the desired assembly of the image sensor and the circuit substrate.

### BACKGROUND OF THE INVENTION

1. Field of the Invention

The present invention relates in general to a method for aligning electronic components, in particular to the alignment of image sensors to a circuit substrate.

2. Description of the Prior Art

Image sensors have been adopted in digital cameras and digital video cameras to capture image data. There are generally two types of image sensors; namely, Charge-Coupled Device (CCD) and Complementary Metal Oxide Semiconductor (CMOS), widely used in the digital camera industry. CMOS image sensors tend to be gradually becoming a replacement for CCD sensors because of lower power usage, integration of additional circuitry on-chip and lower system cost.

Referring initially to FIG. 1, an image sensor 120 is mounted on a circuit substrate 110. The circuit substrate 110 and the image sensor 120 are electrically connected by means of bond wires 130. When CMOS image sensor is employed in digital cameras or digital video cameras for picture capture, it is common that the image sensor 120 does not mount conformably on the circuit substrate 110 and the CMOS image sensor is easily tilted with respect to the circuit substrate 110 because of non-uniform thickness of solder balls for electrically connecting the image sensor 120 to the bond wires 130 or because of inadvertent movement of the image sensor 120 with respect to the circuit substrate 110 during assembly process, for example, by surface mount technology (SMT), as is well known to those of skill in the art. This improper alignment or fixation of the image sensor 120 and circuit substrate 110 results in defocusing after lens unit is attached, and subsequently, it will impair the quality of image data captured by digital cameras or digital video cameras. A number of techniques have been proposed for solving the problems set forth above. However, they are more complicated and labor intensive, and thus, are not suitable for mass production. One of the various examples of the conventional techniques is to manually adjust lens unit relative to the image sensor until the proper focus was attained.

### SUMMARY OF THE INVENTION

It is therefore an object of the invention to provide a method for aligning image sensor so as to precisely position the image sensor on the circuit substrate, streamline manufacture process and increase manufacture yield.

A further object of this invention is to provide a method for aligning image sensor so as to insure the alignment of the image sensor with the circuit substrate and to maintain the preciseness and consistency of the assembly of the image sensor and the circuit substrate in mass production.

Another object of this invention is to provide an alignment device for image sensor so as to insure the alignment of the image sensor with the circuit substrate and to maintain the preciseness and consistency of the assembly of the image sensor and the circuit substrate in mass production.

In accordance with one aspect of the present invention, a method for aligning an image sensor comprises the steps of providing a circuit substrate and an image sensor, providing a device for aligning the image sensor with the circuit substrate, and assembling the circuit substrate, the image sensor and the device so as to maintain the preciseness and consistency of the assembly of the image sensor and the circuit substrate.

In accordance with another aspect of the present invention, a device for aligning an image sensor comprises a frame having a receptacle and an opening at the center thereof. The image sensor is received within the receptacle. The peripheral dimension of the image sensor is smaller than that of the opening so that the image sensor is confined in the opening. The alignment device insures the desired assembly of the image sensor and the circuit substrate. In addition, a connecting device is provided to fix the frame and the image sensor on the circuit substrate. Also, the image sensor can be adjusted relative to the circuit substrate, if necessary.

### BRIEF DESCRIPTION OF THE DRAWINGS

These and other features and advantages of the present invention will be better understood by considering the following detailed description of the invention which is presented with the attached drawings.

FIG. 1 is a schematic view of the known assembly of a CMOS sensor and a circuit substrate;

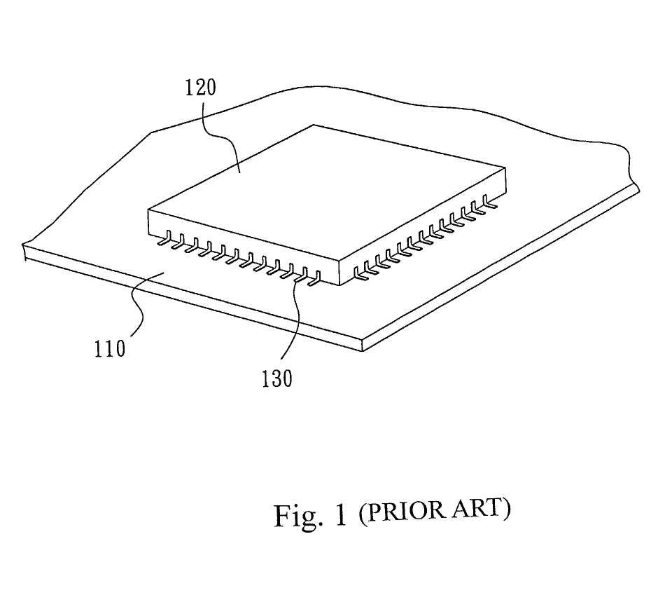

FIG. 2 is a perspective view of an alignment device in accordance with one embodiment of the present invention;

FIG. 3 is a perspective view of an assembly of the alignment device, the image sensor and the circuit substrate of FIG. 2; and

FIG. 4 is a cross-sectional view taken along line I-I of FIG. 3.

### DESCRIPTION OF THE PREFERRED EMBODIMENTS

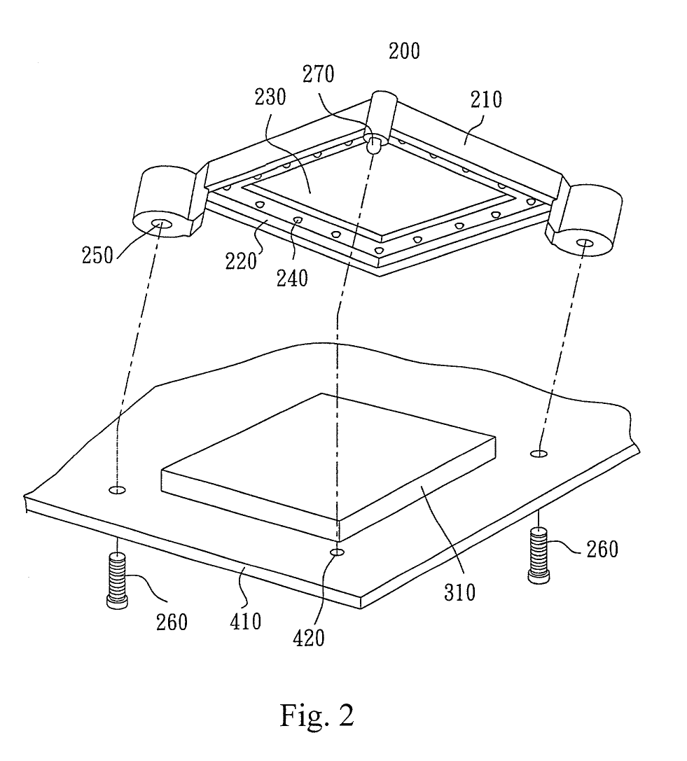

Referring now to FIGS. 2 through 4, a CMOS image sensor 310 is mounted on a circuit substrate 410, as is known in the prior art. In contrast to the conventional alignment techniques, an alignment device 200 for aligning the image sensor 310 to the circuit substrate 410 is provided in accordance with the present invention, as shown in FIG. 2. The alignment device 200, the image sensor 310 and the circuit substrate 410 are assembled together, and therefore, precise alignment of the image sensor 310 with the circuit substrate 410 is obtained. Moreover, the present invention has advantages to maintain the consistency of the assembly of the circuit substrate and the image sensor in mass manufacture process.

The method for aligning image sensor of the present invention further includes a step of forming an electrical connection between the image sensor 310 and the circuit substrate 410. Preferably, the electrical connection is achieved by SMT with the interconnection solder balls.

To illustrate the above-mentioned method for aligning image sensor in accordance with the present invention, inventor provides an alignment device. The material of the alignment device is not specifically limited, and preferably, is plastic or metal. The method for fabricating the alignment device is not specifically limited, and preferably, it is integrally formed. The height of the frame of the present invention is not specifically limited, and preferably, is lower than the height of CMOS image sensor. The frame can be further secured on the circuit substrate by an adhesive. The position of the connecting device of the alignment device is not specifically limited, and preferably, is located at the periphery of the frame formed integrally therewith. The form of the connecting device is not specifically limited, and preferably, is a combination of threading openings and screws, pillars and slots, male and female fasteners, rivets, cotters or pins. The interior surfaces of the frame may have bumps or projecting patterns to contact the image sensor.

FIG. 2 is a perspective view of an alignment device in accordance with one preferred embodiment of the present invention. As shown in FIG. 2, the alignment device has a rectangular frame 210. The frame 210 has a receptacle 220 at the center thereof to hold the image sensor 310 in position and an opening 230 to allow ambient light to pass through and strike the image sensor 310 to capture image data. The size of the opening 230 of the frame 210 is approximately equal to that of the effective area of the image sensor 310. The interior surfaces of the receptacle 220 of the frame 210 can be plane or have protrusions 240 of a predetermined height for dispersing the pressure exerted on the image sensor 310 as contacted with the upper surface of the image sensor 310. In this preferred embodiment of the present invention, the protrusions 240 are arranged separately on the interior surfaces of the receptacle 220.

Advantageously, a device for connecting the frame 210 to the circuit substrate 410 is placed at two diagonally opposite corners of the frame 210. Further, the connecting device is a combination of threading openings 250 and screws 260, which can be used to slightly adjust the height or horizontal level of the frame 210 relative to the image sensor 310. Another connecting device is used, in an auxiliary manner, to fix the frame 210 on the circuit substrate 410. Preferably, the auxiliary connecting device is integrally formed at the other diagonally opposite corners of the frame 210 to serve as the initial mounting reference for the image sensor 310 when the frame 210 is attached to the circuit substrate 410. To this end, pillars 270 are used to insert into holes 420 pre-set on the circuit substrate 410.

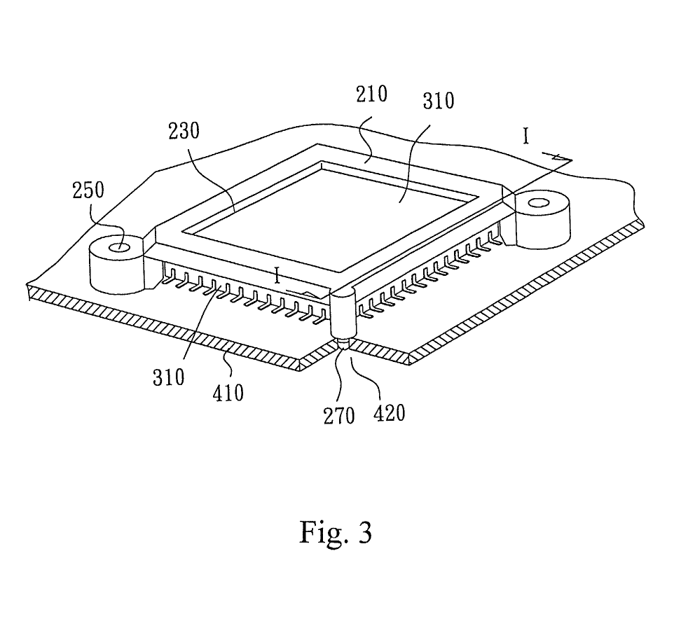

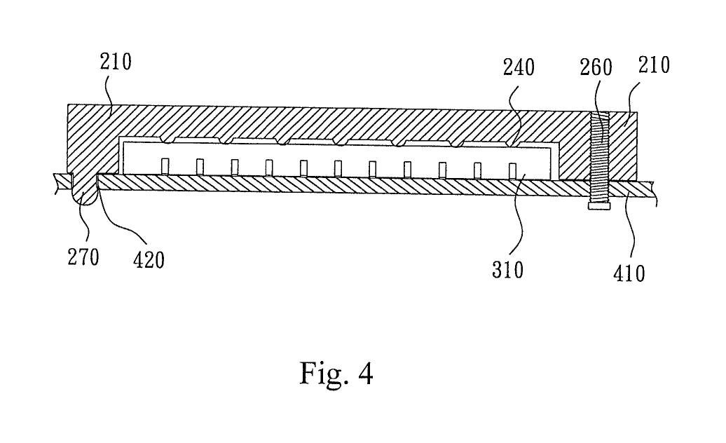

As shown in FIGS. 3 and 4, the image sensor 310 has been placed into the receptacle 220 of the frame 210 of the alignment device. The frame 210, together with the image sensor 310 placed therein, is mounted and fixed on the circuit substrate 410 by aligning the threading openings 250 to the holes 420 of the circuit substrate 410 with screws 260 threading into the openings 250.

After alignment, the image sensor 310 is fixed on the circuit substrate 410 by SMT with interconnection solder balls electrically connected the CMOS image sensor 310 to the bond wires. The height of the frame 210 is lower than that of the image sensor 310; and therefore, the connection between the bond wires and the circuit substrate 410 by SMT can be processed within the space between the frame 210 and the circuit substrate 410.

Occasionally, in case the image sensor 310 still fails to be precisely aligned with the circuit substrate 410 during the electrical connection by SMT or the interconnection balls used in SMT is of rather irregular form, the image sensor 310 has to be further adjusted with respect to a lens unit (not shown) after the lens unit is attached to the circuit substrate. By slightly tightening or loosening the screws 260, the respective vertical position of the image sensor 310 corresponding to the circuit substrate 410 is adjusted to meet the requirement for lens focus, and the precise alignment of the image sensor 310 to the circuit substrate 410 is insured even in such unusual situation.

The present invention has been described in detail with particular reference to preferred embodiments thereof, but it will be understood that variations and modifications can be effected within the spirit and scope of the invention.

1. A method for aligning an image sensor, comprising the steps of:
providing a circuit substrate and an image sensor;
providing a device for aligning said image sensor to said circuit substrate; and
assembling said circuit substrate, said image sensor and said device;
wherein the preciseness and consistency of the assembly of said image sensor and said circuit substrate are maintained.

2. The method of claim 1, further comprising a step of forming electrical connection between said image sensor and said circuit substrate.

3. The method of claim 1, wherein said image sensor is CMOS.

4. The method of claim 1, wherein said image sensor is connected to said circuit substrate by SMT.

5. A device for aligning an image sensor, comprising a frame having a receptacle to receive an image sensor and a central opening of which peripheral dimension is larger than that of said image sensor so that said image sensor is aligned with a circuit substrate.

6. The device of claim 5, further comprising a connecting device for positioning said image sensor onto said circuit substrate.

7. The device of claim 5, wherein said connecting device can be used to slightly adjusted said image sensor with respect to said circuit substrate.

8. The device of claim 6, wherein said connecting device is a combination of screws and screw openings.

9. The device of claim 7, wherein said connecting device is a combination of screws and screw openings.

10. The device or claim 6, wherein said connecting device is a combination pillars and holes.

11. The device of claim 5, wherein the height of said image sensor is higher than that of said frame mounted on said circuit substrate.
